(19) United States
(12) Patent Application Publication
(10) Pub. No.: US 2017/0084547 A1
(43) Pub. Date: Mar. 23, 2017

(54) SEMICONDUCTOR DEVICE, LEAD FRAME, AND METHOD OF MANUFACTURING LEAD FRAME

(71) Applicant: SII Semiconductor Corporation, Chiba-shi (JP)

(72) Inventor: Mami ITO, Chiba-shi (JP)

(21) Appl. No.: 15/264,101

(22) Filed: Sep. 13, 2016

(30) Foreign Application Priority Data
Sep. 18, 2015 (JP) 2015-185775

(51) Int. Cl. H01L 23/00; H01L 21/56; H01L 23/31; H01L 23/495; H01L 21/48

(52) U.S. Cl. CPC H01L 23/562; H01L 23/49503; H01L 23/49551; H01L 23/4952; H01L 21/4842; H01L 23/3114; H01L 21/4825; H01L 21/565

(57) ABSTRACT

Provided is a lead frame that may prevent resin cracks from occurring in a semiconductor device. When a lead frame (3) is formed through press working, punching burrs (3d) are formed on tips of inner leads (3b) to serve as anchors with respect to a resin (5). The punching burrs (3d) are acute-angled projecting portions formed in a direction of a bottom surface of the semiconductor device.

### BACKGROUND OF THE INVENTION

1. Field of the Invention

The present invention relates to a semiconductor device having a lead frame, to the lead frame, and to a method of manufacturing the lead frame.

2. Description of the Related Art

In FIG. 3, there is illustrated an example of a related-art semiconductor device using a lead frame. A semiconductor device 2 includes a tab 3a with a predetermined shape, on which a semiconductor chip 1 is mounted, leads 3e that include inner leads 3b and outer leads 3c extending from the inner leads 3b, conductive wires 4 configured to connect pads 1a on the semiconductor chip 1 and the inner leads 3b of the leads 3e to each other, and a resin 5 for protecting the semiconductor chip 1, the inner leads 3b, and the conductive wires 4 from external factors through encapsulation thereof.

In the semiconductor device 2, the back surfaces of the outer leads 3c and the tab 3a are exposed from the resin 5. Accordingly the semiconductor device 2 has a good heat dissipation performance. At the same time, however, there is a problem in that the leads 3 and the tab 3a are liable to be separated from the resin 5.

As can be seen from FIG. 3, electrical connection from the semiconductor device to a wiring substrate on which the semiconductor device is mounted is established via the following connections, that is, connection through the conductive wires 4 between the pads 1a, which form predetermined terminal portions of the semiconductor chip 1, and the inner leads 3b of the leads 3e, and connection between the outer leads 3c and wiring lines on a mounting substrate. Adhesiveness between the leads 3e and the resin 5, and connection reliability of the conductive wires 4 are important in securing reliability of the electrical connection. In particular, the adhesiveness of the tab 3a and the leads 3e to the resin 5 is an important factor in securing the connection reliability, and suppression of separation and cracks is important technology.

In this regard, in Japanese Patent Application Laid-open No. 05-82704, there are disclosed a lead frame that is suitable for forming a semiconductor package in which cracks do not occur when the semiconductor package is mounted on the substrate, and a method of manufacturing the lead frame. In particular, the lead frame includes acute-angled projections, which are formed on end portions of a tab main surface of the lead frame on which a semiconductor chip is mounted, and a tapered component arranged around end edge portions of the back surface of the tab on which the semiconductor chip is mounted.

Further, in Japanese Patent Application Laid-open No. 07-142661, there is disclosed a lead frame that improves reliability of connection through conductive wires between pads, which form predetermined terminal portions of the semiconductor chip, and inner leads of leads, and a method of manufacturing the lead frame. In particular, the method includes shaping tips of the inner leads to connect the tips of the inner leads to each other, releasing the connected state of the inner leads after undergoing at least one of plating, annealing, and taping, and pressing down the tips of the inner leads.

However, according to the lead frame disclosed in Japanese Patent Application Laid-open No. 05-82704, there is a need to process a mold so that, during the manufacturing of the lead frame, acute-angled projecting portions may be formed on end portions of a surface on which the semiconductor chip is to be mounted of a tab for mounting the semiconductor chip, and a taper may be formed around end edge portions of a surface opposing the surface of the tab on which the semiconductor chip is to be mounted. Further, this is only a countermeasure for cracks initiated from the tab of the lead frame.

Further, in the method of manufacturing the inner leads disclosed in Japanese Patent Application Laid-open No. 07-142661, there is a need to prepare at least two molds in order to manufacture the inner leads.

### SUMMARY OF THE INVENTION

Hence the present invention aims to provide a lead frame that may reduce cracks initiated from inner leads without the need of processing a mold, a method of manufacturing the lead frame, and a semiconductor device using the lead frame.

In order to solve the problems described above, according to an embodiment of the present invention, the following measures are taken.

First, there is provided a lead frame including a tab on which a semiconductor chip is mounted, inner leads arranged around the tab, and outer leads extending from the inner leads, in which punching burrs are formed on tips of the inner leads.

Further, there is provided a method of manufacturing a lead frame, including: preparing a metallic plate formed of a predetermined material; and punching, through use of a mold, the metallic plate into a lead frame including a tab and leads, and forming acute-angled projecting portions that have a predetermined angle on end portions of inner leads of the lead frame.

Through use of the measures described above, the cracks initiated from the inner leads can be reduced without increasing the number of processing steps.

### BRIEF DESCRIPTION OF THE DRAWINGS

FIG. 1 is a diagram for illustrating a semiconductor device including a lead frame that has punching burrs formed on inner lead tips during press working according to an embodiment of the present invention.

FIG. 2A, FIG. 2B, and FIG. 2C are diagrams for illustrating an example of the press working for forming the punching burrs on the inner lead tips according to the embodiment of the present invention.

FIG. 3 is a diagram for illustrating an example of a main configuration of a related-art semiconductor device.

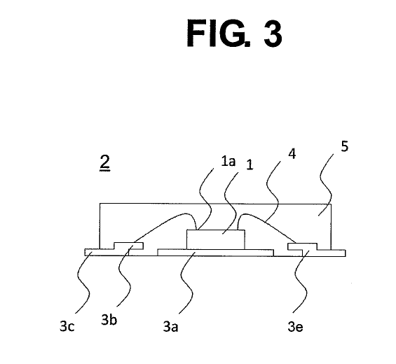

### DETAILED DESCRIPTION OF THE INVENTION

Now, with reference to the drawings, there is given a detailed description of a lead frame of a semiconductor device and a method of manufacturing the lead frame according to an embodiment of the present invention.

In the drawings used in the description given below, features may be drawn in an enlarged manner to clarify the features as a matter of convenience, and the dimension ratio or the like of each component may not always be the same as in reality.

Further, the dimensions described below are only given as examples, and the present invention in not necessarily limit thereto. The present invention may be carried out with different dimensions as long as the gist thereof is not changed.

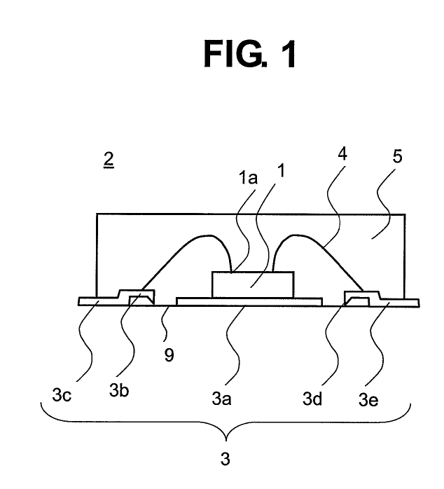

FIG. 1 is a diagram for illustrating the semiconductor device 2 including the lead frame that has punching burrs 3d formed on inner lead tips during press working according to the embodiment of the present invention.

As illustrated in FIG. 1, the lead frame 3 according to the embodiment of the present invention includes a tab 3a with a predetermined shape, on which the semiconductor chip 1 is mounted, and leads 3e, which are arranged around the tab to be spaced apart therefrom and which is configured to extract electrical connection to a substrate. The leads 3e include inner leads 3b and outer leads 3c, which are extended from the inner leads 3b to be bent downward. Further, the leads 3e have the punching burrs 3d formed on the tips of the inner leads 3b through press working.

The semiconductor device 2 schematically includes the lead frame 3 including the tab 3a on which the semiconductor chip 1 is mounted, conductive wires 4 configured to electrically connect pads 1a that form predetermined terminal portions arranged on a front surface of the semiconductor chip 1, to the inner leads 3b of the leads 3, and a resin 5 that is arranged to protect the semiconductor chip 1, the inner leads 3b, and the conductive wires 4 from external factors. The resin 5 covers and encapsulates the semiconductor chip 1, the inner leads 3b, and the conductive wires 4 without any gaps.

The punching burrs 3d formed in a downward direction on the tips of the inner leads 3b in a direction of a bottom surface 9 of the semiconductor device 2 serve as anchors for the resin 5, to thereby prevent the leads 3e from falling off the resin and to also prevent the resin from cracking. The punching burrs 3d provided on the tips of the inner leads 3b are formed when a metallic plate formed of a predetermined material is molded into the inner leads 3b through press working.

The method of manufacturing the semiconductor device is now taken into consideration. In assembling the semiconductor device, when the pads 1a that form the predetermined terminal portions of the semiconductor chip 1, and the inner leads 3a are connected to each other by the conductive wires 4, there is a possibility in that portions near the inner lead tips may be raised above from a top surface of a heat block due to the punching burrs 3d formed on the inner lead tips through the press working. This prevents a bonding region of the inner leads 3b from being sufficiently heated, thereby causing a bonding failure, which needs to be avoided. The bonding failure may be prevented through use of a wire bonder apparatus, which enables the punching burrs 3d formed on the inner lead tips through the press working to escape, to thereby connect the conductive wires 4 to a region that is on an outer leads 3c side of the punching burrs 3d formed on the inner lead tips through the press working, the outer leads 3c extending from the inner leads 3b.

The structure of the wire bonder apparatus that enables the punching burrs 3d formed on the inner lead tips through the press working to escape is described in Japanese Patent Application Laid-open No. 2006-202941, for example.

Next, the method of manufacturing the leads 3 according to the present invention is described.

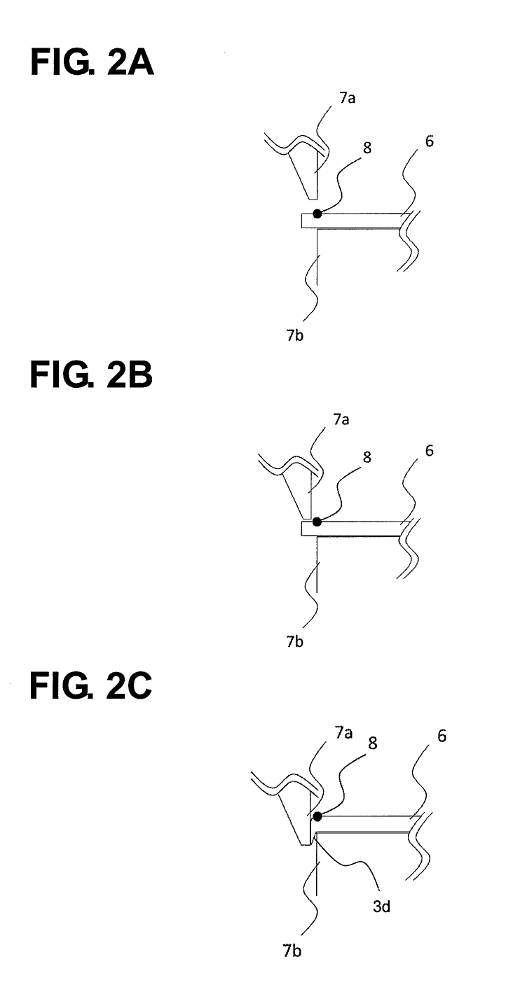

FIG. 2A to FIG. 2C are diagrams for illustrating the method of manufacturing the lead frame that has the punching burrs 3d formed on the inner lead tips during the press working according to the present invention.

As illustrated in FIG. 2A to FIG. 2C, in the method of manufacturing the lead frame according to the present invention, the punching burrs 3d are formed on the inner lead tips during the press working using shapes of an upper mold 7a and a lower mold 7b of a mold 7. The mold 7 is used for punching and molding a metallic plate (the inner leads) 6 formed of a predetermined material (copper, permalloy, etc.) into the lead frame 3.

Now, the method is described in the order of processing. First, as illustrated in FIG. 2A, the lower mold 7b is arranged at the bottom surface of the metallic plate 6 to secure the metallic plate 6. A starting point 8 of bending is located above and in the vicinity of the upper end portion of the lower mold 7b. The upper mold 7a is arranged at a position that is slightly deviated from the starting point 8 in a direction away from the lower mold 7b. Next, as illustrated in FIG. 2B, the upper mold 7a is moved downward. Then, as in FIG. 2C, a tip of the metallic plate 6 is pressed downward, thereby forming the punching burr 3d in a downward direction on the tip thereof. The outer surface of the punching burr 3d is in contact with the upper mold 7a, and this outer surface forms the edge surface of the tip that is a part of the surface of the inner lead. It is preferred that the length of the punching burrs 3d be half the thickness of the outer leads illustrated in FIG. 1 or shorter, without protruding from the bottom surface 9 of the outer leads. In this way, the resin between the punching burrs and the outer leads is joined with the resin in the vicinity of the tab, thereby providing a robust form of resin.

The length of the punching burrs 3d on the inner lead tips and the thickness of the punching burrs when seen in cross section may be defined by the point angle of the upper mold 7a that forms the mold 7 needed to mold the leads 3, and the distance in horizontal direction between the upper mold 7a and the lower mold 7b.

Further, the location of the starting point 8 of the punching burrs 3d may also be defined through a positional relationship in vertical direction between the upper mold 7a and the lower mold 7b. The location of the starting point 8 is important in connecting the conductive wires 4, which connects the pads 1a, which form the predetermined terminal portions of the semiconductor chip 1, and the inner leads 3a of the lead frame 3 to each other, to a region on the outer leads 3c side, the outer leads 3c extending from the inner leads 3b.

As described above, through controlling the length and thickness of the punching burrs 3d on the inner lead tips or the location of the starting point 8, there can be avoided the bonding failure that is caused as below. Specifically, in the assembling of the semiconductor device, when the pads 1a of the semiconductor chip 1 and the inner leads 3a are connected to each other through the conductive wires 4, the portion near the inner lead tips is raised above from the top surface of the heat block due to the punching burrs 3d, thereby preventing the bonding region of the inner leads 3b from being sufficiently heated. Further, it is possible to prevent the punching burrs 3d from being exposed from the bottom surface 9 of the semiconductor device.

Further, according to the present invention, strength of the semiconductor device 2 itself may be secured through improvement of a pull-out strength of the inner leads 3b from the resin 5 with respect to the cracks initiated from the inner leads 3b.

The lead frame of the semiconductor device and the method of manufacturing the lead frame according to the present invention are applicable to semiconductor devices that include a lead frame that is manufactured through press working.

What is claimed is:

1. A lead frame, comprising:
a tab on which a semiconductor chip is to be mounted;
inner leads arranged around the tab;
outer leads extending from the inner leads; and
punching burrs comprising acute-angled projecting portions formed in a downward direction on tips of the inner leads.

2. A lead frame according to claim 1, wherein the acute-angled projecting portions are configured to protrude from a surface opposing a conductive-wire connection surface of the inner leads, and an outer surface of the acute-angled projecting portions form an edge surface of the tips the inner leads.

3. A lead frame according to claim 1, wherein the acute-angled projecting portions have a length that is half a thickness of the outer leads or shorter.

4. A method of manufacturing a lead frame, comprising:
preparing a metallic plate formed of a predetermined material; and
punching, through use of a mold, the metallic plate into a lead frame comprising a tab and leads, and forming acute-angled projecting portions in a downward direction, which have a predetermined angle on end portions of inner leads of the lead frame.

5. A semiconductor device, comprising:
a semiconductor chip;
a tab on which the semiconductor chip is mounted;
inner leads arranged around the tab;
outer leads extending from the inner leads;
punching burrs comprising acute-angled projecting portions formed in a downward direction on tips of the inner leads;
conductive wires configured to electrically connect pads formed on a front surface of the semiconductor chip, and the inner leads to each other; and
a resin for encapsulating the semiconductor chip, the inner leads, and the conductive wires.
